(19) United States
(12) Patent Application Publication
(10) Pub. No.: US 2014/0264904 A1
(43) Pub. Date: Sep. 18, 2014

(54) UNIFIED PCB DESIGN FOR SSD APPLICATIONS, VARIOUS DENSITY CONFIGURATIONS, AND DIRECT NAND ACCESS

(71) Applicant: Apple Inc., Cupertino, CA (US)

(72) Inventors: Anthony Fai, Palo Alto, CA (US); Evan R. Boyle, Cupertino, CA (US); Zhiping Yang, Cupertino, CA (US); Zhonghua Wu, Cupertino, CA (US)

(21) Appl. No.: 13/801,104

(22) Filed: Mar. 13, 2013

(51) Int. Cl. H01L 23/498; H01L 21/50

(52) U.S. Cl. CPC H01L 23/49827; H01L 21/50
USPC 257/774; 438/107

(57) ABSTRACT

Memory systems and methods for creating the same are disclosed. The memory systems can include pairs of IC packages mounted on either side of a system substrate. Contacts formed on the IC packages can be communicatively coupled with contacts of a paired IC package using vias that extend through the system substrate. The IC packages can further communicate with a controller mounted on one side of the system substrate using the vias as well as conductive traces formed in the system substrate.

### BACKGROUND

Various types of nonvolatile memory (“NVM”), such as flash memory (e.g., NAND flash memory and NOR flash memory), can be used for mass storage. For example, consumer electronic devices (e.g., portable media players) use flash memory to store data, including music, videos, images, and other media or types of information. An ongoing trend in the consumer electronic industry involves utilizing more and more NVM in smaller and smaller devices, creating the necessity for creative packaging solutions that increase data storage density.

### SUMMARY

Memory systems and methods for creating the same are provided. A memory system can include a number of memory packages mounted on two sides of a system substrate. Each memory package may be mounted to the system substrate using a package substrate such as, for example, a land grid array (“LGA”), ball grid array (“BGA”), or pin grid array (“PGA”). A memory controller can communicate with the memory packages via electrical connections provided by the system substrate, which can be, for example, a printed circuit board (“PCB”) or printed wiring board (“PWB”).

A package substrate may include an array of contacts for conveying signals to and from components included within its corresponding memory package. In some embodiments, these contacts may be split between two communications channels and arranged symmetrically when reflected about a central axis or a point of rotational symmetry. Accordingly, the communications channels of memory packages mounted on either side of the system substrate can be shorted together to reduce the footprint required for routing the electrical connections on the system substrate.

### BRIEF DESCRIPTION OF THE DRAWINGS

The above and other aspects of the invention, its nature, and various features will become more apparent upon consideration of the following detailed description, taken in conjunction with the accompanying drawings, in which like reference characters refer to like parts throughout, and in which:

FIG. 1 is a diagram depicting an illustrative system that includes a host and an NVM package with a memory controller in accordance with various embodiments;

FIG. 2 is a diagram depicting an example system that includes a memory device with a host controller;

FIG. 3 is a schematic cross-sectional view of memory device in accordance with various embodiments;

FIG. 4 is another schematic cross-sectional view of a memory device in accordance with various embodiments;

FIG. 5 is a perspective view of an NVM package in accordance with various embodiments;

FIG. 6 shows a view of individual contacts of two NVM packages communicatively coupled using vias in accordance with some embodiments;

FIG. 7 is a schematic perspective view of a portion of memory device 702 in accordance with some embodiments; and

FIG. 8 is a flowchart of process for manufacturing a memory device in accordance with various embodiments.

### DETAILED DESCRIPTION

Surface mount packages for integrated circuits (“ICs”) have become prevalent in recent years as the number of interconnects required for each IC has increased beyond the capabilities of traditional through-hole IC packages (e.g., dual-inline packages (“DIP”) and pin-grid arrays (“PGA”)). Examples of surface mount IC packages include ball-grid arrays (“BGA”) and land-grid arrays (“LGA”). A BGA or LGA can include an array of contacts arranged in an x-y plane on a bottom surface of the package substrate. The contacts can be soldered to corresponding contacts of a second substrate such as, for example, a PCB or a PWB. The second substrate can include conductive traces for carrying signals to and from the IC package.

The contacts on the bottom surface of the package substrate can be routed to the top surface using conductive vias formed through the package substrate, for example. The package substrate can also include conductive pads and/or traces on the top surface of the package substrate for communicatively coupling to one or more ICs mounted on top of the package substrate. In some embodiments, wire-bond pads can be formed on the top surface of the package substrate for communicatively coupling the contacts to the IC(s). Additionally, the first IC in a stack can be flip-chip bonded to the top surface of the package substrate. In some embodiments, the IC package can be a NVM package, and the flip-chip bonded IC can be a memory controller for the NVM package.

The contacts formed on the bottom side of the package substrate can be arranged such that a first set of contacts (e.g., a first channel) can be arranged on one portion of package substrate and a second set of contacts (e.g., a second channel) can be arranged on a second portion of the package substrate. The first set of contacts can be dedicated to a subset half of the NVM dies and the second set of contacts can be dedicated to a second subset of the NVM dies. Furthermore, the contacts dedicated to each channel can be arranged symmetrically (e.g., with reflective symmetry about a central axis or about a central point of rotational symmetry). Symmetrical arrangement of the contacts can allow for NVM packages mounted on either side of a system substrate to share electrical connections (e.g., vias) formed through the system substrate as disclosed below.

FIG. 1 is a diagram depicting system 100, including host 102 and NVM package 104. Host 102 may communicate with NVM package 104, which can include memory controller 106, host interface 110, and memory dies 112a-n with corresponding NVMs 128a-n. Host 102 can be any of a variety of host devices and/or systems, such as a portable media player, a cellular telephone, a pocket-sized personal computer, a personal digital assistant (“PDA”), a desktop computer, a laptop computer, and/or a tablet computing device. NVM package 104 can include NVMs 128a-n (e.g., in the memory dies 112a-n) and can be a ball grid array package or other suitable type of integrated circuit (“IC”) package. NVM package 104 can be part of and/or separate from host 102. For example, host 102 can be a board-level device and NVM package 104 can be a memory subsystem that is installed on the board-level device. In other embodiments, NVM package 104 can be coupled to host 102 with a wired (e.g., SATA) or wireless (e.g., Bluetooth™) interface.

Host 102 can include host controller 114 that is configured to interact with NVM package 104. For example, host 102 can transmit various access requests, such as read, program, and erase operations, to NVM package 104. Host controller 114 can include one or more processors and/or microprocessors that are configured to perform operations based on the execution of software and/or firmware instructions. Additionally and/or alternatively, host controller 114 can include hardware-based components, such as application-specific integrated circuits (“ASICs”), that are configured to perform various operations. Host controller 114 can format information (e.g., commands, data) transmitted to NVM package 104 according to a communications protocol shared between host 102 and NVM package 104.

Host 102 can include storage component 134, including volatile memory 108 and NVM 118. Volatile memory 108 can be any of a variety of volatile memory types, such as cache memory or RAM. Host 102 can use volatile memory 108 to perform memory operations and/or to temporarily store data that is being read from and/or written to NVM package 104. For example, volatile memory 108 can temporarily store a queue of memory operations to be sent to, or to store data received from, NVM package 104. Host 102 can use NVM 118 to persistently store a variety of information, including firmware, which can be used to control operations on host 102.

Host 102 can communicate with NVM package 104 over communications channel 116. Communications channel 116 can be fixed (e.g., fixed communications channel), detachable (e.g., universal serial bus (USB), serial advanced technology (SATA)), or wireless (e.g., Bluetooth™). Interactions with NVM package 104 can include providing access requests and transmitting data, such as data to be programmed to one or more of memory dies 112a-n, to NVM package 104. Communication over communications channel 116 can be received at host interface 110 of NVM package 104. Host interface 110 can be part of and/or communicatively connected to memory controller 106.

Like host controller 114, memory controller 106 can include one or more processors and/or microprocessors 120 that are configured to perform operations based on the execution of software and/or firmware instructions. Additionally and/or alternatively, memory controller 106 can include hardware-based components, such as ASICs, that are configured to perform various operations. Memory controller 106 can perform a variety of operations, such as performing access requests initiated by host 102.

Host controller 114 and memory controller 106, alone or in combination, can perform various memory management functions, such as garbage collection and wear leveling. In implementations where memory controller 106 is configured to perform at least some memory management functions, NVM package 104 can be termed “managed NVM” (or “managed NAND” for NAND flash memory). This can be in contrast to “raw NVM” (or “raw NAND” for NAND flash memory), in which host controller 114, external to NVM package 104, performs memory management functions for NVM package 104.

In some embodiments, memory controller 106 can be incorporated into the same package as memory dies 112a-n. In other embodiments, memory controller 106 may be physically located in a separate package or in the same package as host 102. In some embodiments, memory controller 106 may be omitted, and all memory management functions that are normally performed by memory controller 106 (e.g., garbage collection and wear leveling) can be performed by a host controller (e.g., host controller 114).

Memory controller 106 may include volatile memory 122 and NVM 124. Volatile memory 122 can be any of a variety of volatile memory types, such as cache memory or RAM. Memory controller 106 can use volatile memory 122 to perform access requests and/or to temporarily store data that is being read from and/or written to NVMs 128a-n in memory dies 112a-n. For example, volatile memory 122 can store firmware and memory controller 106 can use the firmware to perform operations on NVM package 104 (e.g., read/program operations). Memory controller 106 can use NVM 124 to persistently store a variety of information, such as debug logs, instructions, and firmware that NVM package 104 uses to operate.

Memory controller 106 can use shared internal bus 126 to access NVMs 128a-n, which may be used for persistent data storage. Although only one shared internal bus 126 is depicted in NVM package 104, an NVM package can include more than one shared internal bus. Each internal bus can be connected to multiple (e.g., 2, 3, 4, 8, 32, etc.) memory dies as depicted with regard to memory dies 112a-n. Memory dies 112a-n can be physically arranged in a variety of configurations, including a stacked configuration, and may be, according to some embodiments, IC dies. According to some embodiments, memory dies 112a-n arranged in stacked configurations can be electrically coupled to memory controller 106 with conductive epoxy traces. These embodiments will be discussed in more detail with respect to FIGS. 3-5 below.

NVMs 128a-n can be any of a variety of NVM, such as NAND flash memory based on floating gate or charge trapping technology, NOR flash memory, erasable programmable read only memory (“EPROM”), electrically erasable programmable read only memory (“EEPROM”), ferroelectric RAM (“FRAM”), magnetoresistive RAM (“MRAM”), phase change memory (“PCM”), or any combination thereof.

FIG. 2 is a diagram depicting an system 200, which can includes a memory device 202 with a memory controller 206. Memory device 202 may be similar to system 100 described above with respect to FIG. 1, with host controller 206 being similar to the host controller 106. As disclosed in greater detail below, memory device 202 can include NVM packages (e.g., NVM packages 204a-n, which may correspond to NVM package 104 described above with regard to FIG. 1). Memory device 202 can be any of a variety of memory devices, such as a portable media player, a cellular telephone, a pocket-sized personal computer, a personal digital assistant (PDA), a desktop computer, a laptop computer, a tablet computing device, and/or a removable/portable storage device (e.g., a flash memory card, a USB flash memory drive, or a solid state drive (“SSD”)).

Memory device 202 is depicted as including memory controller 206 and NVM 205. Memory controller 206 can be similar to memory controller 106, described above with regard to FIG. 1, except that it may reside outside of, and perform memory management functions for all of, the individual the NVM packages 204a-n of system 200. Memory controller 206 can include one or more processors 220 and volatile memory 222. Processors 220 can be any variety of processors, such as microprocessors, central processing units (CPUs), graphics processing units (GPUs), for example, or any combination thereof. Volatile memory 222 can be any of a variety of volatile memory, such as RAM and cache memory. Volatile memory 222 can be used by the processors 220 to perform various operations, such as retrieving and processing data stored in NVM 205.

NVM 205 can include one or more NVM packages 204a-n. NVM packages 204a-n can each be similar to NVM package 104 described above with regard to FIG. 1. For example, NVM packages 204a-n can each include a plurality of memory dies with NVM (e.g., memory dies 112a-n and NVMs 128a-n), one or more memory controllers (e.g., memory controller 106), and/or interfaces that are configured to provide improved data reliability and/or signal integrity (e.g., host interface 110). In an exemplary embodiment, however, NVM packages 204a-n may be raw NVM packages without embedded memory controllers. Rather, memory controller 206 can perform memory management functions for all NVM packages in NVM 205. NVM 205 can include any number of NVM packages (e.g., 2, 3, 4, 8, 16, etc.).

The system 200 is depicted as also including an external device 214 that can be communicatively connected (directly and/or indirectly) to the memory device 202. Communication between external device 214 and memory device 202 can include the transmission of data and/or instructions between the two devices. External device 214 can be any of a variety of electronic devices, such as a portable media player, a cellular telephone, a pocket-sized personal computer, a personal digital assistant (“PDA”), a desktop computer, a laptop computer, a tablet computing device desktop computer, a server system, and/or a media computing device (e.g., a media server, a television, a stereo system). In some embodiments, external device 214 may correspond to host 102 of FIG. 1, and management of NVM 205 can be performed by memory controller 206 and/or one or more external controllers such as host controller 114 of FIG. 1. Memory device 202 can communicate with external device 214 via a physical and/or wireless connection using an external device interface 216 (e.g., wireless chip, USB interface, etc.).

According to some embodiments, memory device 202 can be a SSD and external device 214 can be a desktop computer that can transmit data (e.g., audio files, video files, etc.) to, and received data from, the memory device over a physical or wireless connection.

FIG. 3 is a schematic cross-sectional view of a memory device 302 in accordance with various embodiments. Memory device 302 can include NVM packages 304a-h and memory controller 306 coupled to a system substrate 310. Vias 330 and traces 332 can be formed within system substrate 310 to communicatively couple memory controller 306 to NVM packages 304a-h. According to some embodiments, system substrate 310 may be a PCB or PWB. Memory device 302 can correspond to memory device 202 of FIG. 2, for example. One skilled in the art will appreciate that although memory device 302 includes 8 NVM packages, any suitable number of NVM packages may be included in memory device 302.

NVM packages 304a-h may include multiple NVM dies (e.g., NVM dies 112a-n of FIG. 1) communicatively coupled to an integrated circuit (“IC”) package substrate. Examples of IC package substrates include ball-grid arrays (“BGA”) and land-grid arrays (“LGA”). A BGA or LGA can include an array of contacts arranged in an x-y plane on a bottom surface of the package substrate. The contacts can be soldered to corresponding contacts, or bond pads, of a second substrate such as, for example, system substrate 310.

In particular, the contacts on the bottom surface of the NVM packages 304a-h can be routed to the NVM dies using conductive vias formed through the package substrate. NVM packages 304a-h can also include conductive pads and/or traces on the top surface of the package substrate for communicatively coupling to one or more NVM dies. In some embodiments, wire-bond pads can be formed on the top surface of the package substrate for communicatively coupling the contacts to the IC(s). Additionally, the first IC in a stack can be flip-chip bonded to the top surface of the package substrate.

The contacts formed on the bottom side of NVM packages 302a-h can be arranged such that a first set of contacts (e.g., contacts associated with a first communications channel) can be arranged on a first portion of the package substrate closest and a second set of contacts (e.g., contacts associated with a second communications channel) can be arranged on a second portion of the package substrate. According to some embodiments, the first channel can be dedicated to a first subset of the NVM dies, and the second channel can be dedicated to a second subset of the NVM dies.

The contacts dedicated to each channel may be symmetrically placed about a central axis of symmetry. Contacts dedicated to each channel can be arranged on either side of the axis of symmetry such that NVM packages mounted on either side of system substrate 310 can have vertically coordinating contact arrays. That is, each contact of an NVM package mounted on a first side 310a of package substrate 310 (e.g., NVM package 304a) can be vertically aligned with identical contacts of an NVM package mounted on a second side 310b of system substrate 310 (e.g., NVM package 304b). Each pair of vertically aligned, coordinating contacts can be communicatively coupled, and shorted together, using vias 330 formed through package substrate 310.

According to further embodiments, the contacts of NVM packages 304a-h may be symmetrically placed about a central point of rotational symmetry. Contacts dedicated to each channel can be arranged on either side of a central axis drawn through the point of rotational symmetry. In such embodiments, while each contact of an NVM package mounted on a first side 310a of package substrate 310 (e.g., NVM package 304a) can be vertically aligned with a contact of an NVM package mounted on a second side 310b (e.g., NVM package 304b) of system substrate 310, the vertically aligned contacts may not be correspond identically to one another. For example, an chip enable contact for NVM package 304a may be vertically aligned with a read enable contact for NVM package 304b. Accordingly, because each pair of vertically aligned, coordinating contacts can be communicatively coupled, and shorted together, using vias 330 formed through package substrate 310, memory controller 306 may be use alternate contact maps for pairs of NVM packages mounted on either side of system substrate 310.

Memory controller 306 can communicate with NVM packages 304a-n using vias 330 and conductive traces 332. Vias 330 may be electrically conductive pathways that extend from first side 310a of package substrate 310 to second side 310b of package substrate 310. In some embodiments, holes may be mechanically drilled or chemically etched through package substrate 310. The holes may then be filled with a conductive material to form vias 330. The conductive material can be any material suitable for the purpose. According to some embodiments, the hole can be metalized using an electroplating process or other suitable metallization process. In other embodiments, the holes can be filled with a conductive epoxy.

Additionally, vias 330 may terminate at contacts formed on first side 310a and second side 310b for communicatively coupling to the contacts formed on the bottom surface of NVM packages 304a-h. The contacts may be bond pads formed where vias 330 emerge from the surface of package substrate 310 to facilitate connections between vias 330 and other contacts of NVM packages 304a-h. In some embodiments, NVM packages 304a-h may be communicatively coupled to the bond pads that terminate vias 330 using solder connections, for example.

Memory controller 306 can be electrically connected to vias 330, and ultimately NVM packages 304a-h, with conductive traces 332 as depicted schematically in FIG. 3. According to some embodiments, conductive traces 332 can be deposited on surfaces of individual PCB or PWB layers that are stacked and physically coupled together (e.g., using an adhesive) to form system substrate 310. Conductive traces 332 may be formed using, for example, a tape-automated bonding (“TAB”) process or a lithographic printing process. In other embodiments, system substrate 310 may be a single layer PCB or PWB, and traces 332 may be deposited on first side 310a and/or second side 310b of system substrate 310.

As depicted in FIG. 3, NVM packages 304a-h of memory device 302 can be dual-channel memory devices. Accordingly, the contacts associated with both channels of each NVM package may be communicatively coupled to memory controller 306. The vias that communicatively couple vertically aligned NVM packages can, therefore, be split into two groups for each vertically aligned pair. These groups may be represented schematically as vias 330a (e.g., vias dedicated to a first channel of a vertically aligned pair of NVM packages) and vias 330b (e.g., vias dedicated to a second channel of a vertically aligned pair of NVM packages). In should be understood that although vias 330 are drawn schematically in FIG. 3, each via depicted may represent a bundle of vias, where each via is communicatively coupled to an individual contact of an NVM package. Similarly, separate conductive traces may be formed for communicatively coupling to each via. Accordingly, sharing each via between two NVM packages halves the number of conductive traces and vias required to couple memory controller 306 to NVM packages 304a-h.

Memory controller 306 may use package enable and chip enable signals to differentiate between NVM packages 304a-h as well as individual NVM dies within each NVM package, respectively.

FIG. 4 is a schematic cross-sectional view of a memory device 402 in accordance with various embodiments. Memory device 402 can include NVM packages 404a-h and memory controller 406 coupled to a system substrate 410. Vias 430 and traces 432 can be formed within system substrate 410 to communicatively couple memory controller 406 to NVM packages 404a-h. Memory device 402 can correspond to memory device 302 of FIG. 3, with the exception that only one channel of each of NVM packages 402a-h is communicatively coupled to the memory controller.

Communicatively coupling memory controller 406 to only one channel of each NVM package 404a-h may be beneficial for a number of reasons. For example, single-channel communications between memory controller 406 and NVM packages 404a-h can improve signal integrity by reducing cross-talk over high-speed signal lines and allowing for more direct communications to NVM dies within each NVM package compared with dual-channel memory devices. Additionally, the number of vias 430 and conductive traces 432 required to manufacture memory device 402 are halved compared to the dual-channel implementation disclosed above with respect to memory device 302 of FIG. 3, and routing of conductive traces 432 through memory device 402 may be significantly less complex.

FIG. 5 is a schematic perspective view of a memory device 502 in accordance with various embodiments. Memory device 502 may correspond to the single-channel memory device 402 of FIG. 4, for example. Accordingly, memory device 502, NVM packages 504a-h, memory controller, 506, vias 530, conductive traces 532 and system substrate 510 can correspond to memory device 402, NVM packages 404a-h, memory controller, 406, vias 430, conductive traces 432, and system substrate 410 of FIG. 4. NVM packages 504b, 504d, 504f, and 504h are drawn in dashed lines to indicate that they are mounted on the bottom surface 510b of system substrate 510 and, therefore, would not be visible in a perspective view of memory device 502.

Channels 504a[0,1]-504h[0,1] are also represented in FIG. 5. Each channel can represent a set of contacts associated with a communications channel of each NVM package. Accordingly, NVM package 504a can include channels 504a[0] and 504a[1], NVM package 504b can include channels 504b[0] and 504b[1], and so on for each of NVM packages 504a-h.

Each of channels 504a[0,1]-504h[0,1] may be schematically represented as an X or an O depending on whether or not it is an active channel for that particular NVM package. Therefore, channel 504a[0], represented as an O, can be an active channel for NVM package 504a, while channel 504a[1], represented as an X, may be an inactive communications channel. Furthermore, vertically aligned channels (e.g., channel 504a[0] and channel 504b[0]) corresponding to vertically aligned NVM packages (e.g., NVM package 504a and NVM package 504b) on either side of system substrate 510 may have identical active/inactive statuses. For example, channel 504a[0] and channel 504b[0], which can be vertically aligned, may be active channels, while channel 504a[1] and channel 504b[1], also vertically aligned, may be inactive channels.

As noted above with respect to FIG. 4, such an arrangement may offer potential benefits regarding the routing of conductive traces 532 through memory device 502. In particular, conductive traces 532 may be routed directly to vias 530 associated with an active channel, potentially directly under or over inactive channels of one or more NVM packages. For example, the conductive traces 532 coupling controller 506 to the contacts associated with active channels 504a[0] and 504b[0] can pass directly under the contacts associated with inactive channels 504c[0] and 504d[0] because the vias associated with these inactive channels may be omitted, leaving an unobstructed path to active channels 504a[0] and 504b[0]. Similarly, because conductive traces 532 may terminate at vias 330 associated with the contacts of an active channel, total trace length may be reduced for active channels close to memory controller 506 (e.g., conductive traces 532 routed to active channels 504c[1] and 504d[1]) without extending to NVM packages of memory device 502 furthest from memory controller 506.

As noted above with respect to FIG. 3, however, memory device 502 may be a dual-channel memory device. In a some embodiments of a dual-channel memory device, where channels 504a[0,1]-504h[0,1] are all active, individual sets of conductive traces 532 can be formed to communicatively couple memory controller 506 to each channel. In these embodiments, conductive traces 532 extending to NVM packages furthest from memory controller 506 (e.g., NVM packages 504a and 504b) may be routed around vias 330 associated with NVM packages situated closer to memory controller 506 (e.g., NVM packages 504c and 504d). Such embodiments may require increasing the footprint of memory device 502 in order to accommodate the traces.

In other embodiments, conductive traces 532 may communicatively couple together contacts of NVM packages that are not vertically aligned with respect to system substrate 510. That is, one set of conductive traces 532 may extend from memory controller 506 to a first set of vias 330 (e.g., vias 330 communicatively coupling channels 504c[1] and 504d[1]) and then continue on to a second set of vias 330 (e.g., vias 330 communicatively coupling channels 504a [1] and 504b[1]). Such an arrangement allows for dual-channel memory device operation without increasing the footprint of memory device 502. Memory controller 506 may differentiate signals transmitted to and received from the various interconnected channels using various chip enable and package enable signals, for example.

FIG. 6 shows a view of individual contacts of two NVM packages 604a and 604b communicatively coupled using vias in accordance with some embodiments. NVM packages 604a and 604b may include contacts associated with channels 604a[0,1] and 604b[0,1], respectively. Further, the individual contacts of channel 604a[0] can be coupled to the individual contacts of channel 604b[0], and the individual contacts of channel 604a[1] can be coupled to the individual contacts of channel 604b[1], with vias 630. Although not depicted in FIG. 6, NVM packages 604a and 604b can be mounted on a system substrate (e.g., system substrate 310 of FIG. 3), and vias 330 can extend through the system substrate.

In the embodiment depicted in FIG. 6, the contacts dedicated to each channel of an NVM package (e.g., channels 504a[0] and 504a[1]) may be symmetrically placed about a central axis of symmetry 670. Contacts dedicated to each channel can be arranged on either side of the axis of symmetry 670 such that a NVM package (e.g., NVM package 604b) can be rotated upside down along the axis of symmetry. As a result, when NVM package 604b is mounted on a system substrate and vertically aligned with NVM package 604a, the contacts of NVM package 604b pins can coordinate, and be vertically aligned, with the contacts of NVM package 604a. Thus, identically corresponding contacts of NVM package 604a and NVM package 604b can be communicatively coupled together using vias 630.

FIG. 7 is a schematic perspective view of a portion of memory device 702 in accordance with some embodiments. In particular, memory device 702 can include NVN packages 704a and 704b, channels 704a[p,1] and 704[0,p], vias 730, and conductive traces 732. Memory device 702 may be a single-channel memory device similar to memory device 402 of FIG. 4, except that vertically aligned communications channels (e.g., channels 704a[p] and 704b[0]) may not have identical active/inactive statuses. That is, channels 702a[p] and 702b[p] may be inactive, while their vertically aligned counterparts, 702b[0] and 702a[1], respectively, may be active channels.

According to some embodiments, inactive channels 702a[p] and 702b[p] may be isolated from vias 330 using, for example, a non-conductive solder paste. However, any suitable method of electrically isolating channels 702a[p] and 702b[p] from vias 330 may be used. Rather than communicatively coupling a memory controller (e.g., memory controller 406 of FIG. 4) to channels 702a[p] and 702b[p], the terminal ends of vias 730 associated with these channels may be used for direct probing of active channels 704b[0] and 704a[1]. That is, channels 702a[p] and 702b[p] may be probe points that allow direct access to NVM with NVM packages 704a and 704b.

Beneficially, all of the same system components used to construct a dual-channel memory device (e.g., dual channel memory device 302 of FIG. 3) can be included to form memory device 702, which can allow for direct NVM probing ny simply electrically isolating the contacts associated with channels 702a[p] and 702b[p] during assembly of memory device 702. Additionally, each NVM package of memory device 702 may be assembled in this way to allow for direct probing of all, or any subset of NVM packages in the memory device.

FIG. 8 is a flowchart of an illustrative process 800 for forming a memory system in accordance with some embodiments. At step 801, a system substrate including conductive traces, vias, and bond pads can be provided. In some embodiments, the system substrate may be a multi-layer PCB or PWB in which conductive traces (e.g., conductive traces 332 of FIG. 3) can be formed on surfaces of one or more of the layers. In other embodiments, the system substrate can be a monolithic PCB or PWB in which conductive traces can be formed on the outer surface of the system substrate.

Vias (e.g., vias 330 of FIG. 3) may be formed to extend fully through the system substrate and terminate on outer surfaces of the system substrate (e.g., first side 310a and second side 310b of system substrate 310). Holes may be mechanically drilled or chemically etched through the package substrate and the holes may then be filled with a conductive material to form the vias. The conductive material can be any material suitable for the purpose (e.g., a metal or a conductive epoxy). Bond pads may be formed to terminate vias on opposing sides of the system substrate.

At step 803, a subset of the bond pads may be optionally covered with an electrically isolating material. For example, after the system substrate is provided, bond pads associated with inactive communications channels (e.g., channels 704a[p] and 704b[p] of FIG. 7) in a single channel memory device (e.g., memory device 702 of FIG. 7) can be covered with an electrically isolating material, such as a nonconductive paste, for example. This subset of bond pads can serve as probe points for directly accessing ICs of IC packages that will be communicatively coupled to the bond pads.

At step 805, IC packages can be coupled to the opposite sides of the system substrate with vertically aligned contacts of the IC packages communicatively coupled with the vias. According to some embodiments, the IC packages can be NVM packages (e.g., NVM packages 304a-h of FIG. 3) and or memory controllers (e.g., memory controller 306 of FIG. 3) of a memory device (e.g., memory device 302 of FIG. 3). The IC packages may be LGAs or BGAs that can be coupled to the bond pads using solder balls that communicatively couple individual contacts formed on the bottom surface of the IC packages with individual bond pads.

According to some embodiments, the contacts formed on the bottom of NVM packages coupled to the system substrate may be symmetrically arranged, such that each contact of an NVM package may be vertically aligned with a corresponding contact of an NVM package mounted on the opposite side of the system substrate. Accordingly, the vias can communicatively couple these vertically aligned contacts with each other, and to the memory controller using the conductive traces.

It is to be understood that the steps shown in process 800 of FIG. 8 are merely illustrative and that existing steps may be modified or omitted, additional steps may be added, and the order of certain steps may be altered.

While there have been described memory systems and methods for making the same, it is to be understood that many changes may be made therein without departing from the spirit and scope of the invention. Insubstantial changes from the claimed subject matter as viewed by a person with ordinary skill in the art, no known or later devised, are expressly contemplated as being equivalently within the scope of the claims. Therefore, obvious substitutions now or later known to one with ordinary skill in the art are defined to be within the scope of the defined elements.

The described embodiments of the invention are presented for the purpose of illustration and not of limitation.

What is claimed is:

1. A memory device comprising:
a system substrate comprising: vias extending from a first side of the system substrate to a second side of the system substrate and conductive traces extending perpendicular to the vias; and
a plurality of IC packages communicatively coupled to the first side and the second side system substrate, wherein:
pairs of the plurality NVM packages mounted on the first side and the second side system substrate are vertically aligned; and
the vias communicatively couple the pairs of NVM packages together.

2. The memory device of claim 1, wherein the IC packages comprise nonvolatile memory (“NVM”) packages.

3. The memory device of claim 2, further comprising a memory controller communicatively coupled to the first side of the system substrate and the plurality of NVM packages with the vias and conductive traces.

4. The memory device of claim 2, wherein each NVM package comprises NVM dies and a package substrate.

5. The memory device of claim 2, wherein each NVM package comprises an array of contacts, and wherein the array of contacts is split between two communications channels.

6. The memory device of claim 5, wherein the two communications channels are arranged symmetrically about a central axis of symmetry.

7. The memory device of claim 5, wherein the two communications channels are arranged symmetrically about a point of rotational symmetry.

8. The memory device of claim 5, wherein the vias communicatively couple each contact of the array of contacts with a corresponding contact of the array of contacts of the paired NVM package.

9. A method for manufacturing a memory device, the method comprising:
providing a system substrate comprising conductive traces and vias; and
coupling pairs of IC packages to the opposite sides of the system substrate, wherein vertically aligned contacts of the pairs of IC packages are communicatively coupled with the vias.

10. The method of claim 9, further comprising coupling a controller to one side of the system substrate, wherein the controller is communicatively coupled to the IC packages with the conductive traces and the vias.

11. The method of claim 9, wherein the system substrate further comprises bond pads terminating the vias on the sides of the system substrate.

12. The method of claim 11, further comprising covering a subset of the bond pads with an electrically isolating material.

13. The method of claim 12, wherein the electrically isolating material comprises a nonconductive paste.

14. The method of claim 9, wherein the vertically aligned contacts comprise identically functioning, corresponding contacts for the pair of NVM packages.

15. A system comprising a memory device, the memory device comprising:
a first nonvolatile memory (“NVM”) package communicatively coupled to a first side of a system substrate;
a second NVM package communicatively coupled to a second side of the system substrate, wherein each NVM package comprises an array of contacts, and wherein the array of contacts are vertically aligned through the system substrate; and
vias communicatively coupling the vertically aligned contacts.

16. The system of claim 15, wherein the array of contacts for each of the first NVM package and the second NVM package is separated into two communications channels.

17. The system of claim 16, wherein contacts associated with the two communications channels are symmetrically arranged about a central axis of symmetry.

18. The system of claim 17, wherein contacts associated with the two communications channels are symmetrically arranged about a central point of rotational symmetry.

19. The system of claim 15, further comprising conductive traces extending perpendicular to and communicatively coupled to the vias within the system substrate.

20. The system of claim 16, wherein one of the two communications channels of each NVM package is inactive, and wherein the contacts associated with the inactive communications channels are not communicatively coupled to vias.

21. The system of claim 20, wherein the contacts associated with the inactive communications channels are electrically isolated from the vias using a nonconductive paste.

22. The system of claim 21, wherein the vias separated from the inactive communications channel of the first NVM package with the nonconductive paste provide probing points to directly probe the second NVM package.

23. The system of claim 20, wherein the contacts associated with the inactive communications channels not placed adjacent to any vias.
